(19) United States
(12) Patent Application Publication
(10) Pub. No.: US 2026/0123369 A1
(43) Pub. Date: Apr. 30, 2026

(54) CONDUCTIVE LINE WITH GEOMETRY FOR REDUCED CRACKING

(71) Applicant: Taiwan Semiconductor Manufacturing Company, Ltd., Hsinchu (TW)

(72) Inventors: Yi-Hui Chen, Changhua County (TW); Yi-Lii Huang, Zhubei City (TW); Chih-Hsiao Chen, Taichung City (TW); Jung-You Chen, Zhubei City (TW); Hui-Hsuan Kung, Taichung City (TW); Yi-Chen Li, Taichung City (TW)

(73) Assignee: Taiwan Semiconductor Manufacturing Company, Ltd., Hsinchu (TW)

(21) Appl. No.: 18/918,988

(22) Filed: Oct. 17, 2024

(51) Int. Cl. H01L 23/00; H01L 21/768; H01L 23/528

(52) U.S. Cl. CPC H10W 20/01; H10W 20/435; H10W 72/01951; H10W 72/923; H10W 72/9445; H10W 90/792

(57) ABSTRACT

Semiconductor structures and methods of fabrication are provided. A semiconductor structure includes an interconnect structure lying over a semiconductor substrate and having a top metal feature; a pad lying over the interconnect structure; and an extended conductive line having a proximal end electrically connected to the pad and extending to a distal end, wherein the extended conductive line include a proximal portion extending in a first direction and a non-proximal portion extending in second direction transverse to the first direction, and wherein the extended conductive line is electrically connected to the top metal feature.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography and etching processes to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise within each of the processes that are used, and these additional problems should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-10 illustrate cross-sectional views of intermediate processing steps in forming a semiconductor die according to an embodiment.

FIG. 11 is an overhead schematic of a pad having a main body and an extended connection line with a non-linear geometry, in accordance with embodiments herein.

FIG. 12 is an overhead schematic of the extended connection line of FIG. 11, in accordance with embodiments herein.

FIG. 13 is an overhead schematic of a pad having a main body and an extended connection lines with non-linear geometries, in accordance with embodiments herein.

FIG. 14 is an overhead schematic of two adjacent pads, with each pad having a main body and an extended connection lines with non-linear geometries, and with the extended connection lines being interleaved, in accordance with embodiments herein.

FIG. 15 is a focused overhead schematic of adjacent extended connection lines with non-linear geometries from two adjacent pads, in accordance with embodiments herein.

FIGS. 16 and 17 are cross-sectional views of the device of FIG. 15, in accordance with embodiments herein.

FIGS. 18-20 are overhead schematic of two adjacent pads, with each pad having a main body and an extended connection lines, and with the extended connection lines being interleaved, in accordance with embodiments herein.

FIG. 21 is an overhead schematic view of the extended connection lines of FIG. 20, in accordance with embodiments herein.

FIGS. 22-33 are overhead schematic of two adjacent pads, with each pad having a main body and an extended connection lines, and with the extended connection lines being interleaved, in accordance with embodiments herein.

FIG. 34 is a flow chart illustrating a method for fabrication a semiconductor structure, in accordance with embodiments herein.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “over”, “overlying”, “above”, “upper”, “top”, “under”, “underlying”, “beneath”, “below”, “lower”, “bottom”, “side”, and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

When a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

In certain embodiments herein, a “material structure” is a structure that includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material; and a structure that is formed of a “material” includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material. For example, certain embodiments, each of a tungsten structure and a structure formed of tungsten is a structure that is at least 50 wt. %, at least 60 wt. %, at least 75 wt. %, at least 90 wt. %, at least 95 wt. %, or at least 99 wt. % of tungsten.

For the sake of brevity, typical techniques related to semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many typical processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Presented herein are embodiments of semiconductor devices and of methods for fabricating such devices. The present disclosure relates more particularly, to interconnect structures for integrated circuit devices. Methods described herein may be easily integrated into the current process flow.

The device structures shown in the figures of the present disclosure is simplified and not all features in the device structures are illustrated or described in detail. The device structures shown in the figures may be a portion of an IC chip, a system on chip (SoC), or portion thereof, that may include various passive and active microelectronic devices such as resistors, capacitors, inductors, diodes, p-type field effect transistors (PFETs), n-type field effect transistors (NFETs), metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, other suitable components, or combinations thereof.

Embodiments herein may provide extended connection lines from aluminum pads which are selectively twisted or bent to reduce stresses that would cause cracking. Certain embodiments provide for adjustable parallel length and spacing of selectively twisted extended connection lines. Certain embodiments provides for adjustable numbers of interconnections between redistribution vias and twisted extended connection lines.

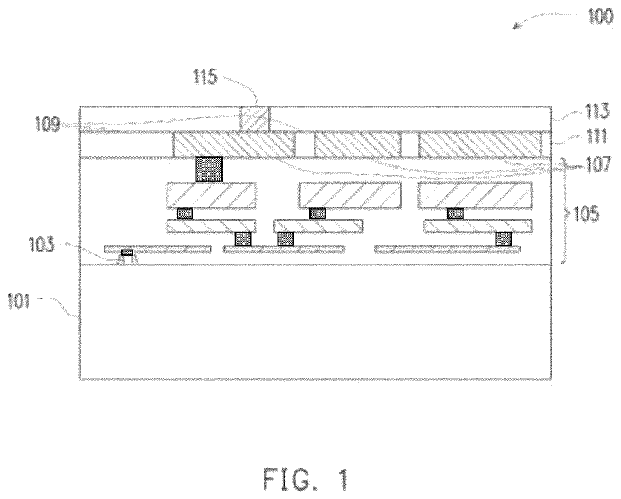

FIG. 1 illustrates a side view of a die 100, which includes a substrate 101. The substrate 101 may be a bulk silicon substrate although other semiconductor materials including group III, group IV, and group V elements may also be used. Active devices 103, such as transistors, may be formed in and/or on the substrate 101. For example, active devices may be two-dimensional planar devices, three-dimensional FinFET devices, and/or three-dimensional Gate-All-Around (GAA) devices.

An interconnect structure 105 is formed over the substrate 101. In some embodiments, the interconnect structure 105 may include at least one dielectric layer formed of low-k dielectric materials having k values, for example, lower than about 4.0. In some embodiments, the dielectric layers of the interconnect structure 105 may be made of, for example, silicon oxide, SiCOH, and the like. As illustrated, the interconnect structure 105 includes metal lines and metal vias (i.e., connections), which are formed in the dielectric layers. For example, the interconnect structure 105 may include a plurality of metal layers that are interconnected through vias. The metal lines and vias may be formed of copper or copper alloys, and they can also be formed of other metals. The metal lines and vias may be formed by etching openings in the dielectric layers, filling the openings with a conductive material, and performing a planarization (such as CMP) to level top surfaces of the metal lines and vias with top surfaces of the dielectric layers.

A top metal layer 111 is formed over the interconnect structure 105. The top metal layer 111 includes a dielectric layer 109 and conductive features 107. The top metal layer 111 is formed by depositing the dielectric layer 109 over the top surface of the interconnect structure 105. The dielectric layer 109 may be deposited by chemical vapor deposition (CVD), physical vapor deposition (PVD), or the like. The dielectric layer may comprise the same material as the dielectric layers of the interconnect structure 105. For example, in some embodiments, the dielectric layer 109 may be made of silicon oxide, SiCOH, and the like.

The dielectric layer 109 may then be etched to form openings exposing the top surface of the interconnect structure 105. The conductive features 107 may be deposited in the openings by, for example, a plating process. The conductive features 107 may then be planarized by a process such as chemical mechanical polishing (CMP). The conductive features 107 may be made of copper or copper alloy. Other materials, such as aluminum, aluminum alloy, or the like may also be used to form the conductive features 107. As shown in FIG. 1, the conductive features 107 may be discrete features. For example, the conductive features 107 may be separated and electrically isolated from each other by the dielectric layer 109. According to other embodiments, the conductive features 107 may be portions of a continuous metallic feature.

A passivation layer 113 may be formed over the top metal layer 111. In an embodiment, the passivation layer 113 may be polybenzoxazole (PBO), although any suitable material, such as benzocyclobutene (BCB), polyimide, or a polyimide derivative, may alternatively be utilized. The passivation layer 113 may be placed using, e.g., a spin-coating process, although any suitable method may alternatively be used.

A redistribution via 115 may be formed in the passivation layer 113. For example, the passivation layer 113 may be patterned to form an opening through which one of the conductive features 107 is exposed. The patterning of the passivation layer 113 may be performed using photolithography techniques. The redistribution via 115 may then be formed in the opening in the passivation layer 113. The redistribution via 115 may be made of aluminum, aluminum alloy, copper, or copper alloy, although other metallic materials may be used.

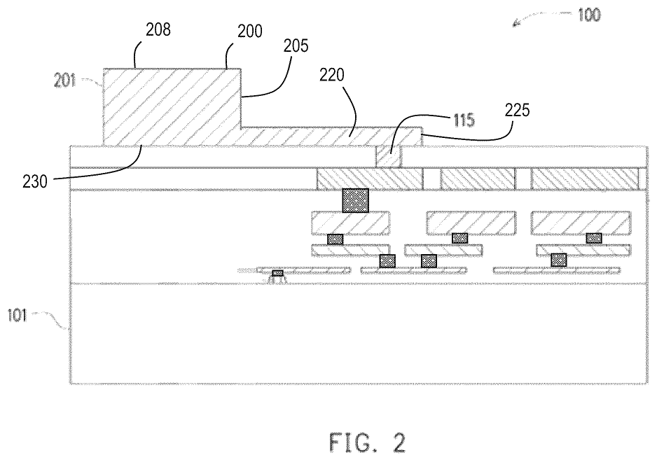

FIG. 2 illustrates the formation of a pad 200. The pad 200 is formed over and contacting the redistribution via 115. The pad 200 is electrically coupled to the active devices 103 through conductive features such as metal lines and vias formed in the interconnect structure 105, the conductive features 107, and the redistribution via 115. The pad 200 may be formed of aluminum or aluminum alloy, although other metallic materials may be used. The pad 200 may be formed by blanket deposition processes. For example, CVD, PVD, or the like may be used to deposit a layer of aluminum over the surface of the passivation layer 113 and the redistribution via 115. A photoresist layer (not separately illustrated) may then be formed over the aluminum layer and the aluminum layer may be etched to form the pad 200.

As shown in FIG. 2, the pad 200 may be formed with a main body 201 and an extended connection line 220. The pad 200 has an upper contact surface 208 that is formed by the main body 201. While FIG. 2 illustrates that the main body 201 and extending connection line 220 are formed integrally and share a contiguous bottom surface 230, in other embodiments, the extending connection line 220 may be formed at a lower level, and the main body 201 may be formed over the extended connection line 220. As shown, the main body 201 has an end surface 205, and the extended connection line 220 extends away from the end surface 205 of the main body 201 to a terminal end 225. In certain embodiments, the main body 201 is not located directly over a redistribution via 115 and the extended connection line 220 extends to a location directly over a redistribution via 115. In this manner, the pad 200 may be formed in electrical connection to a selected redistribution via 115 without positioning the main body 201, and top surface 208, directly over the redistribution via 115.

According to at least one embodiment, the pad 200 and the redistribution via 115 may be formed simultaneously. For example, the passivation layer 113 may be formed over the top metal layer 111 and patterned to expose one of the conductive features 107. The pad 200 and the redistribution via 115 may be formed by blanket deposition. For example, CVD, PVD, or the like may be used to deposit a layer of aluminum over the surface of the passivation layer 113, in the opening formed in the passivation layer 113, and over the exposed conductive feature 107. A photoresist layer (not separately illustrated) may then be formed over the aluminum layer and the aluminum layer may be etched to form the pad 200.

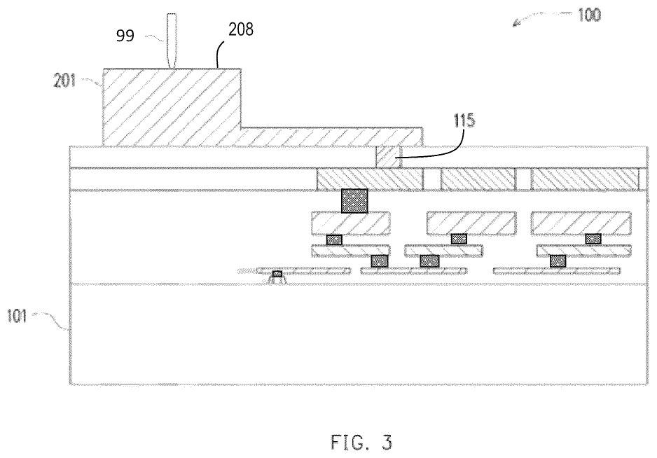

FIG. 3 illustrates a probing step, which may be part of a wafer-acceptance-test or a circuit test. The probing is performed to verify the functionality of the active devices 103 and the respective electrical connections (e.g., connections in the interconnect structure 105, conductive features 107, and redistribution via 115). The probing may be performed by contacting a probe needle 99 to contact surface 208 of the pad 200. The probe needle 99 may be a part of a probe card having a plurality of probe needles, for example, which is connected to testing equipment (not separately illustrated). If the die 100 passes the wafer-acceptance-test, the die is a known good die (KGD).

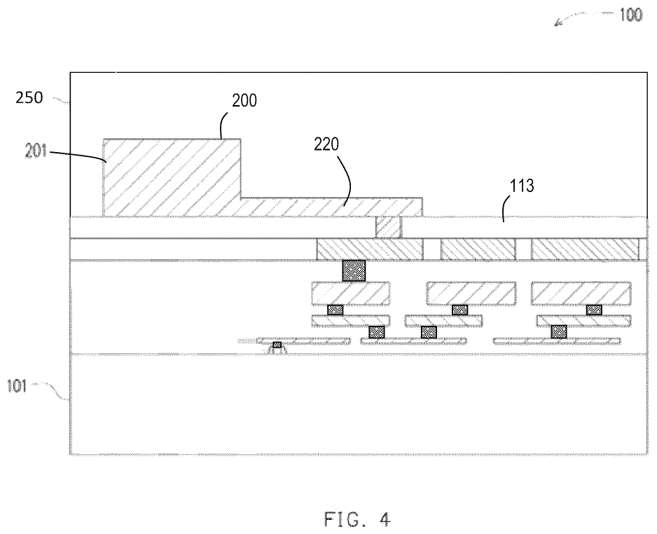

FIG. 4 illustrates the formation of a layer 250. Layer 250 may be a passivation layer. Layer 250 may be a bond layer. Layer 250 is deposited over the top surface of the passivation layer 113 and over top and side surfaces of the pad 200. The layer 250 may be used for fusion bonding (also referred to as oxide-to-oxide bonding). In accordance with some embodiments, the layer 250 is formed of a silicon-containing dielectric material such as silicon oxide, silicon nitride, or the like. The layer 250 may be deposited using any suitable method, such as, CVD, high-density plasma chemical vapor deposition (HDPCVD), PVD, atomic layer deposition (ALD), or the like. The layer 250 may be planarized, for example, in a chemical mechanical polish (CMP) process. The top surface of the layer 250 is higher than the top surface of the pad 200. The layer 250 may be referred to as a passivation layer or a dielectric layer.

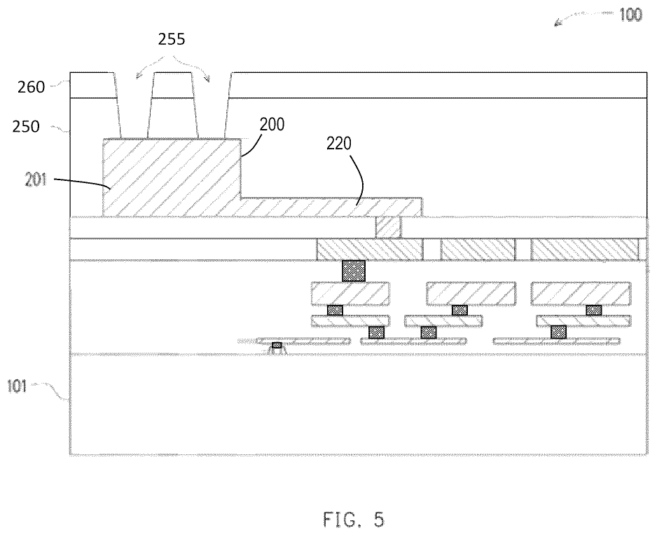

FIG. 5 illustrates the formation of first openings 255 in the layer 250 to expose the pad 200. A first photoresist 260 is applied over the top surface of the layer 250 and patterned. The first photoresist 260 is then used to etch the layer 250 in order to form the first openings 255. The layer 250 may be etched by dry etching (e.g., reactive ion etching (RIE) or neutral beam etching (NBE)), wet etching, or the like. In accordance with some embodiments of the present disclosure, the etching stops on the pad 200 such that the pad 200 is exposed through the first openings 255 in the layer 250.

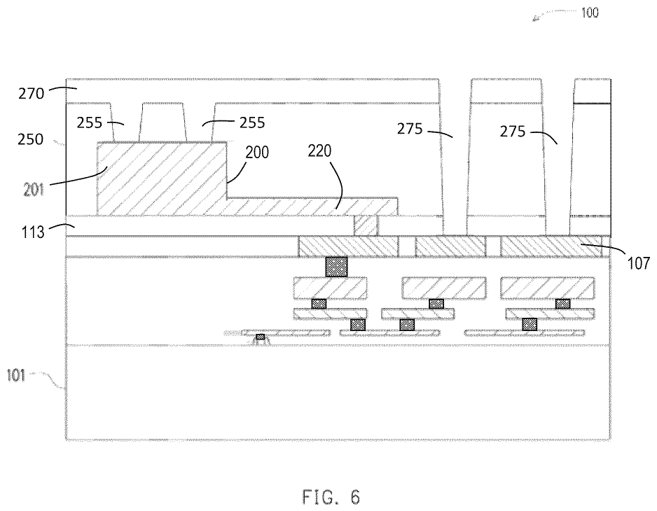

FIG. 6 illustrates the formation of second openings 275 in the layer 250 and the passivation layer 113 to expose the conductive features 107. A second photoresist 270 is applied over top surfaces of the layer 250 and the pad 200 and in the openings 255, and the second photoresist 270 is patterned. The second photoresist 270 is then used along with one or more etches to etch the layer 250 and the passivation layer 113 in order to form the second openings 275. The etches used to form the second openings 275 may be the same or different from the etches used to form the first openings 255 and may include dry etching (e.g., RIE or NBE), wet etching, or the like. In accordance with some embodiments of the present disclosure, the etching stops on the conductive features 107 such that the conductive features 107 are exposed through the second openings 275 in the layer 250 and the passivation layer 113.

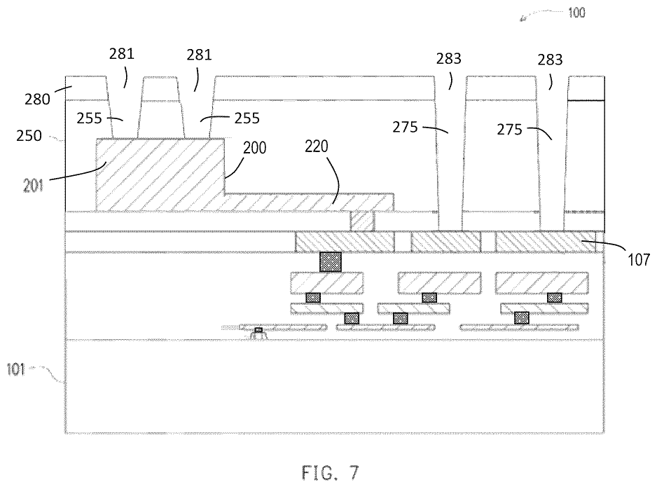

FIG. 7 illustrates an optional formation of third openings 281 and fourth openings 283 in the layer 250 to widen portions of the first openings 255 and the second openings 275, respectively. A third photoresist 280 is applied over top surfaces of the layer 250, pad 200, and conductive features 107 and in the first openings 255 and the second openings 275. The third photoresist 280 is patterned and is then used to etch the layer 250 to form the third openings 281 and fourth openings 283. The layer 250 may be etched by dry etching (e.g., RIE or NBE), wet etching, or the like. The third openings 281 may be formed above the first openings 255 and the pad 200. The fourth openings 283 may be formed above the second openings 275 and the conductive features 107.

FIG. 8 illustrates the filling of the first openings 255, the second openings 275, the third openings 281, and the fourth openings 283 with a seed layer 801 and a plate metal 803. The seed layer 801 may be blanket deposited over top surfaces of the layer 250, the pad 200, and the conductive features 107 and sidewalls of the first openings 255, the second openings 275, the third openings 281, and the fourth openings 283. The seed layer 801 may comprise a copper layer. The seed layer 801 may be deposited using processes such as sputtering, evaporation, or plasma-enhanced chemical vapor deposition (PECVD), or the like, depending upon the desired materials. The plate metal 803 may be deposited over the seed layer 801 through a plating process such as electrical or electro-less plating. The plate metal 803 may comprise copper, a copper alloy, or the like. The plate metal 803 may be a fill material. A barrier layer (not separately illustrated) may be blanket deposited over top surfaces of the layer 250, the pad 200, and the conductive features 107 and sidewalls of the first openings 255, the second openings 275, the third openings 281, and the fourth openings 283 before the seed layer 801. The barrier layer may comprise titanium, titanium nitride, tantalum, tantalum nitride, or the like.

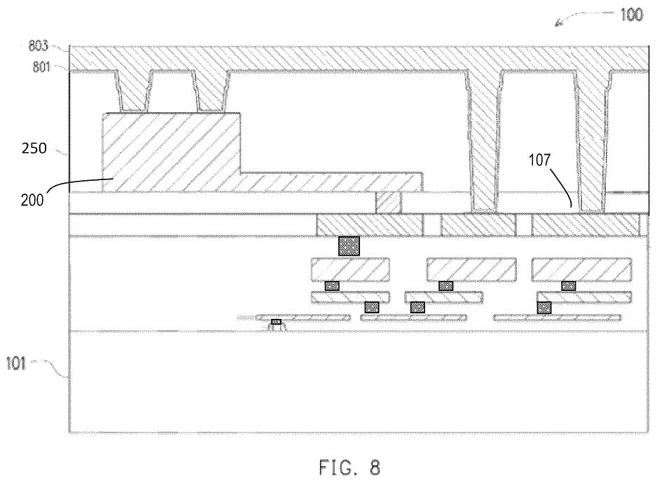

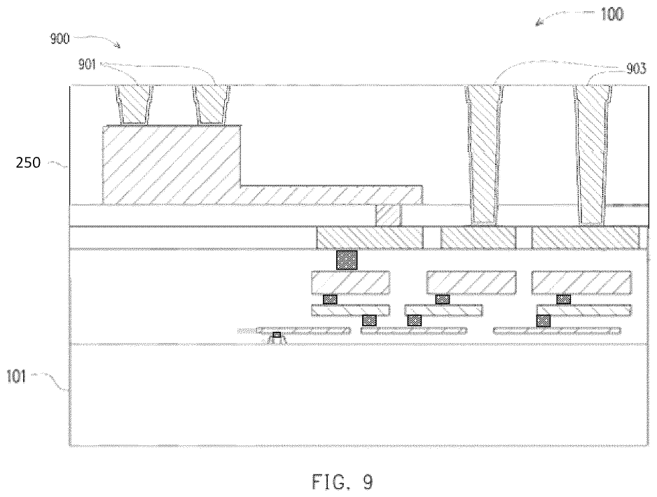

FIG. 9 illustrates a die 900 which includes first bond pads 901 and second bond pads 903. Following the filling of the first openings 255, the second openings 275, the third openings 281, and the fourth openings 283, shown in FIG. 8, a planarization process, such as a CMP, is performed to remove excess portions of the conductive material of the seed layer 801 and the plate metal 803, forming the first bond pads 901 and the second bond pads 903. The first bond pads 901 may contact the pad 200 and the second bond pads 903 may contact the conductive features 107. According to at least one embodiment, the top surfaces of the first bond pads 901 and the second bond pads 903 are coplanar with each other and with the top surfaces of the layer 250. The top portions of the first bond pads 901 fill the third openings 281 and may be referred to as bond pad metals. The top portions of the second bond pads 903 fill the fourth openings 283 and may also be referred to as bond pad metals. The lower portions of the first bond pads 901 fill the first openings 255 and may be referred to as bond pad vias. The lower portions of the second bond pads 903 fill the second openings 275 and may also be referred to as bond pad vias.

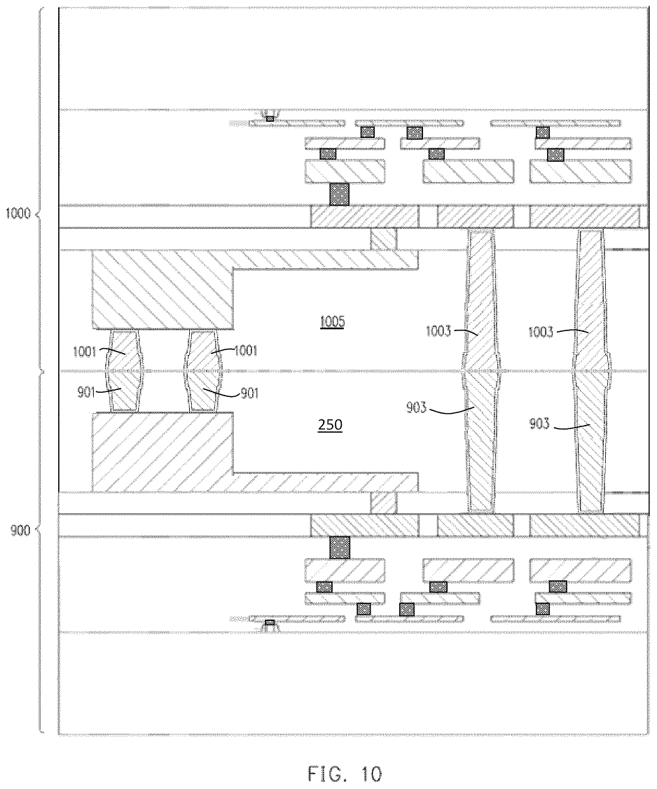

FIG. 10 illustrates a cross-sectional view of a processing step for bonding the die 900 to a package component 1000. In accordance with some embodiments of the present disclosure, the package component 1000 is a device die, an interposer die, a package substrate, or a package. According to an embodiment, the package component 1000 may be a device die which is the mirror image of the die 900. The package component 1000 includes first bond pads 1001, second bond pads 1003, and a dielectric layer 1005. The first bond pads 1001 may be similar to the first bond pads 901, the second bond pads 1003 may be similar to the second bond pads 903, and the dielectric layer 1005 may be similar to the layer 250. For example, the top surface of the dielectric layer 1005 is coplanar with the top surfaces of the first bond pads 1001 and the second bond pads 1003. The first bond pads 1001 and the second bond pads 1003 may comprise a conductive material such as copper, copper alloy, or the like. The dielectric layer 1005 may comprise a silicon-containing dielectric layer such as a silicon oxide layer, a silicon nitride layer, or the like.

In some embodiments, the die 900 is bonded to the package component 1000 by, for example, hybrid bonding. After the top surfaces of the die 900 and the package component 1000 are planarized, the top surfaces of the die 900 and the package component 1000 may be activated. Activating the top surfaces of die 900 and the package component 1000 may comprise a dry treatment, a wet treatment, a plasma treatment, exposure to an inert gas, exposure to H₂, exposure to N₂, exposure to O₂, or combinations thereof, as examples. In embodiments where a wet treatment is used, an RCA cleaning may be used, for example. In another embodiment, the activation process may comprise other types of treatments. The activation process assists in the hybrid bonding of the die 900 and the package component 1000; advantageously allowing the use of lower pressures and temperatures in subsequent hybrid bonding processes.

After the activation process, the die 900 and the package component 1000 may be cleaned using a chemical rinse. The wafer assembly is then subjected to thermal treatment and contact pressure to hybrid bond the die 900 to the package component 1000. The die 900 and the package component 1000 may be subjected to a pressure of about 200 kPa or less, and a temperature between about 200° C. and about 400° C. to fuse the layer 250 and the dielectric layer 1005. The die 900 and the package component 1000 may then be subjected to a temperature at or above the eutectic point for material of the first bond pad 901, the second bond pad 903, the first bond pad 1001, and the second bond pad 1003, e.g., between about 150° C. and about 650° C., to fuse the metal bond pads. In this manner, fusion of the die 900 and the package component 1000 forms a hybrid bonded device. In some embodiments, the bonded dies are baked, annealed, pressed, or otherwise treated to strengthen or finalize the bond.

In other embodiments, the die 900 may be bonded to the package component 1000 by direct surface bonding, metal-to-metal bonding, or another bonding process. A direct surface bonding process creates an oxide-to-oxide bond or substrate-to-substrate bond through a cleaning and/or surface activation process followed by applying pressure, heat and/or other bonding process steps to the joined surfaces. In some embodiments, the die 900 and the package component 1000 are bonded by metal-to-metal bonding that is achieved by fusing conductive elements. For example, the bond pads 1001 and 1003 are bonded to the bond pads 901 and 903, respectively, through metal-to-metal bonding.

The formation of the first bond pads 901 which contact the pad 200 may increase the number of connections that can be made to the active devices 103 in the dies 900. Moreover, the first bond pads 901 which contact the pad 200 may increase the pin out area over devices which do not include the first bond pads 901. For example, the pin out area of the dies 900 may be between about 3,000 pins and about 700 pins greater than the pin out area for a conventional die, such as about 30 percent greater.

It has been found that during formation of the semiconductor die 900 according to FIGS. 1-10, cracking may occur adjacent to long extended connection lines 220, such as between adjacent extended connection lines 220, parallel to conductive features 107 of the top metal layer 111.

Embodiments herein may reduce or eliminate such cracking by providing the extended connection lines 220 with a non-linear geometry.

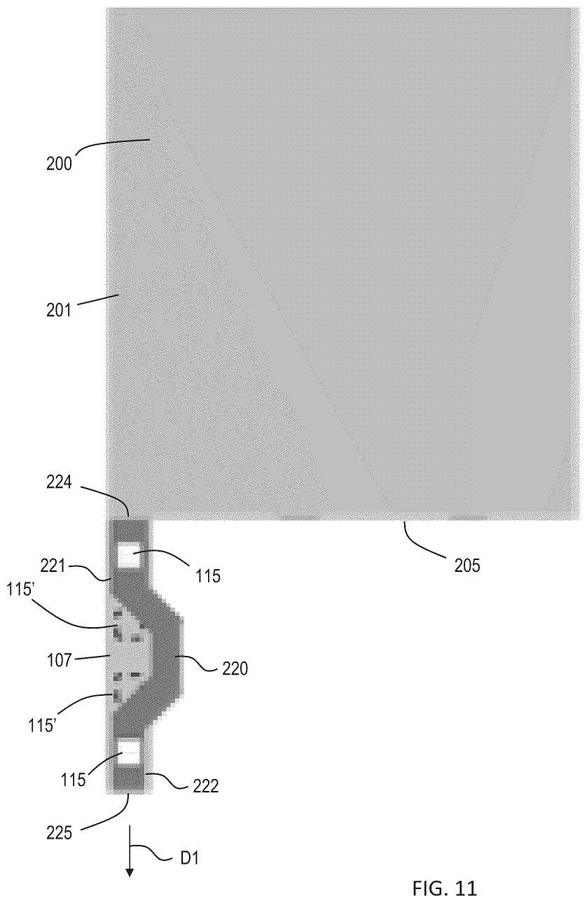

Referring to FIG. 11, a pad 200 is shown with a main body 201 and an extended connection line 220. In FIG. 11, the extended connection line 220 has a non-linear geometry. FIG. 11 is an overhead view and illustrates a top metal conductive feature 107 lying under the non-linear extended connection line 220.

AS shown in FIG. 11, the extended connection line 220 extends in a direction D1 away from a proximal end 224 abutting the end surface 205 of the main body 201 to the terminal end 225. In certain embodiments, direction D1 is perpendicular to the end surface 205 and is perpendicular to the terminal end 225. Extended connection line 220 has a first sidewall 221 and an opposite second sidewall 222.

Underlying redistribution vias 115 electrically connecting the underlying top metal conductive feature 107 and the non-linear extended connection line 220 are shown. Non-used redistribution via locations 115′ are illustrated by dashed lines.

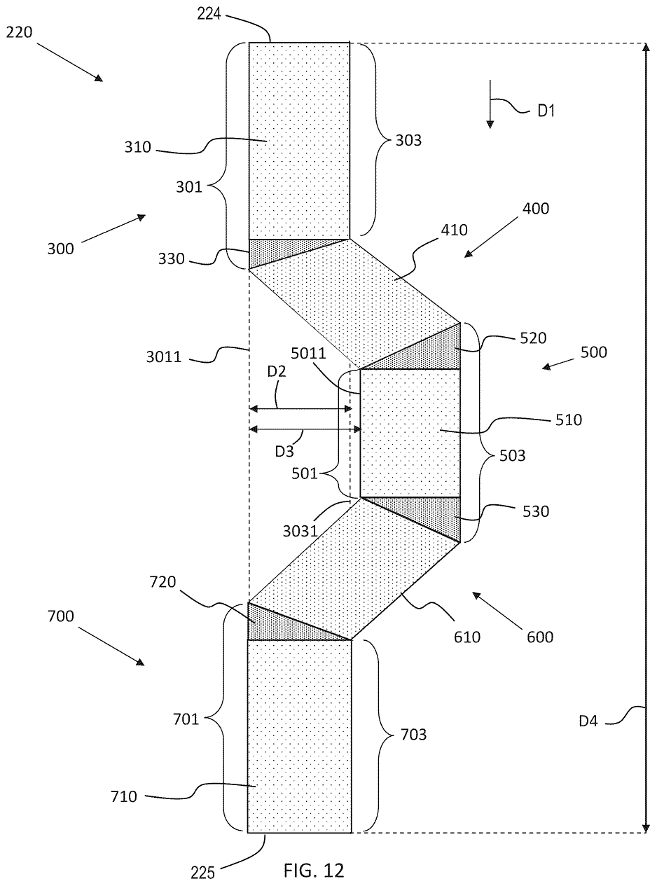

FIG. 12 is an overhead schematic view focused on the non-linear extended connection line 220 of FIG. 11.

In FIG. 12, the non-linear extended connection line 220 is considered to include several sections. Specifically, the non-linear extended connection line 220 includes a proximal linear section 300, an intermediate linear section 500, and a terminal linear section 700. Proximal linear section 300 is connected to intermediate linear section 500 by a proximal transition section 400. Intermediate linear section 500 is connected to terminal linear section 700 by a distal transition section 600. While sections 300, 400, 500, 600, and 700 are described as separate geometric elements, they are structurally integral, i.e., one-piece.

As shown, proximal linear section 300 is formed from a rectangular polygon 310 and a triangular polygon 330. Thus, proximal linear section 300 has a long sidewall 301 and a short sidewall 303 interconnected by end wall 224. As shown, long sidewall 301 is longer than short sidewall 303 in the direction of D1. Rectangular polygon 310 forms proximal end 224 and extends in direction D1 to an interface with triangular polygon 330.

As shown, intermediate linear section 500 is formed from a rectangular polygon 510, a proximal triangular polygon 520, and a distal triangular polygon 530. Thus, intermediate linear section 500 has a long sidewall 501 and a short sidewall 503. As shown, long sidewall 501 is longer than short sidewall 503 in the direction of D1. Rectangular polygon 510 forms an interface with proximal triangular polygon 520 and extends in direction D1 to an interface with distal triangular polygon 530.

As shown, distal linear section 700 is formed from a rectangular polygon 710 and a triangular polygon 720. Thus, proximal linear section 700 has a long sidewall 701 and a short sidewall 703. As shown, long sidewall 701 is longer than short sidewall 703 in the direction of D1. Rectangular polygon 710 forms distal end 225. As shown, rectangular polygon 710 extends in direction D1 from an interface with triangular polygon 720 to distal end 225.

As shown, proximal transition section 400 interconnects triangular polygon 330 and proximal triangular polygon 520. Further, distal transition section 600 interconnects distal triangular polygon 530 and triangular polygon 720.

Rectangular polygon 310 may have a width D2, measured in a direction perpendicular to direction D1. In other words, end wall 224 may have a length D2 and long sidewall 301 may be distanced from short sidewall 303 by distance D2. For example, long sidewall 301 may define, and be co-planar with, a plane 3011 and short sidewall 303 may define, and be co-planar with, a plane 3031. As shown, plane 3031 is distanced from plane 3011 by distance D2, measured in the direction perpendicular to direction D1.

As further shown, short sidewall 501 defines, and is co-planar with, a plane 5011. As shown, plane 5011 is distanced from plane 3011 by distance D3, measured in the direction perpendicular to direction D1.

In the illustrated embodiment, distance D3 is greater than distance D2. For example, distance D3 may be at least 101% of D2, such as at least 102%, at least 103%, at least 104%, at least 105%, at least 106%, at least 107%, at least 108%, at least 109%, at least 110%, at least 115%, at least 120%, at least 125%, at least 130%, at least 135%, at least 140%, at least 145%, at least 150%, at least 155%, at least 160%, at least 165%, at least 170%, at least 175%, at least 180%, at least 185%, at least 190%, at least 195%, at least 200%, at least 220%, at least 240%, at least 260%, at least 280%, or at least 300% of distance D2. Further, distance D3 may be at most 101% of D2, such as at most 102%, at most 103%, at most 104%, at most 105%, at most 106%, at most 107%, at most 108%, at most 109%, at most 110%, at most 115%, at most 120%, at most 125%, at most 130%, at most 135%, at most 140%, at most 145%, at most 150%, at most 155%, at most 160%, at most 165%, at most 170%, at most 175%, at most 180%, at most 185%, at most 190%, at most 195%, at most 200%, at most 220%, at most 240%, at most 260%, at most 280%, or at most 300% of distance D2.

In other embodiments, distance D2 and distance D3 are equal.

In still other embodiments distance D2 is greater than distance D3. For example, distance D2 may be at least 101% of D3, such as at least 102%, at least 103%, at least 104%, at least 105%, at least 106%, at least 107%, at least 108%, at least 109%, at least 110%, at least 115%, at least 120%, at least 125%, at least 130%, at least 135%, at least 140%, at least 145%, at least 150%, at least 155%, at least 160%, at least 165%, at least 170%, at least 175%, at least 180%, at least 185%, at least 190%, at least 195%, at least 200%, at least 220%, at least 240%, at least 260%, at least 280%, or at least 300% of distance D3. Further, distance D2 may be at most 101% of D3, such as at most 102%, at most 103%, at most 104%, at most 105%, at most 106%, at most 107%, at most 108%, at most 109%, at most 110%, at most 115%, at most 120%, at most 125%, at most 130%, at most 135%, at most 140%, at most 145%, at most 150%, at most 155%, at most 160%, at most 165%, at most 170%, at most 175%, at most 180%, at most 185%, at most 190%, at most 195%, at most 200%, at most 220%, at most 240%, at most 260%, at most 280%, or at most 300% of distance D3.

As shown, proximal end wall 224 is distanced from distal end wall 225 by distance D4 in direction D1. Distance D4 is greater than distance D2. For example a D2:D4 ratio may be at least 1:30, such as at least 1:25, at last 1:20, at least 1:18, at least 1:15, at least 1:12, at least 1:10, at least 1:9, at least 1:8, at least 1:6, at least 1:5, or at least 1:4. The D2:D4 ratio may be at most 1:30, such as at most 1:25, at most 1:20, at most 1:18, at most 1:15, at most 1:12, at most 1:10, at most 1:9, at most 1:8, at most 1:6, at most 1:5, or at most 1:4.

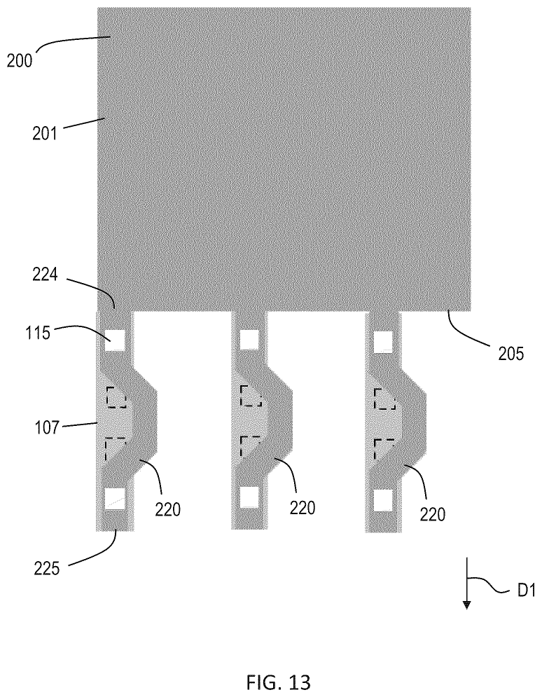

FIG. 13 illustrates that a pad 200 may include more than one extended connection line 220. For example, pad 200 includes three extended connection lines 220. A pad 200 may include any desired number of extended connection lines 220. In FIG. 13, the three extended connection lines 220 each have a non-linear geometry. In fact, in FIG. 13, the three extended connection lines 220 each have a same non-linear geometry. However, a pad 200 may be formed with linear and non-linear extended connection lines 220. Further, a pad 200 may be formed with non-linear extended connection lines 220 having different geometries or shapes. In FIG. 13, each extended connection lines 220 lies directly over a respective top metal conductive feature 107 and is electrically connected by respective redistribution vias 115.

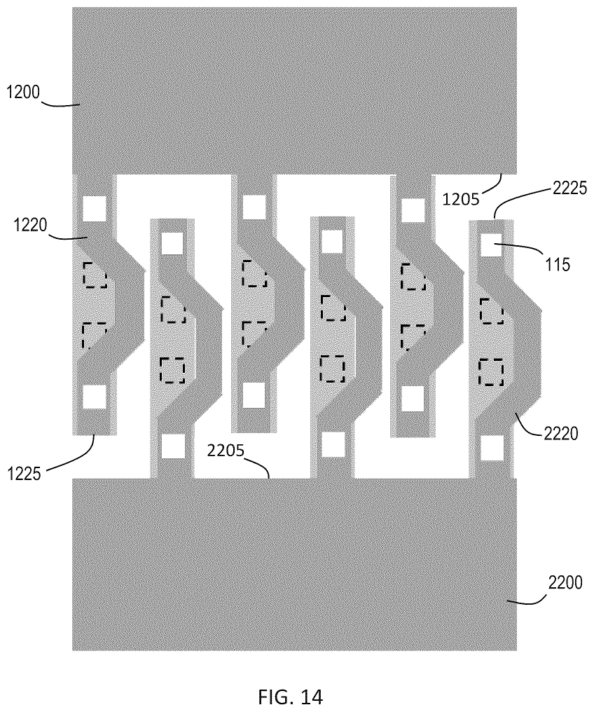

FIG. 14 illustrates two pads 1200 and 2200 that are constructed in accordance with pad 200 described above. As shown pads 1200 and 2200 are adjacent to one another and have extended connection lines 1220 and 2220 that extend toward one another. Extended connection lines 1220 and 2220 are interleaved such that a connection line 1220/2220 from the other pad 1200/2200 is located between each adjacent pair of connection lines 2220/1220 of a pad 2200/1200.

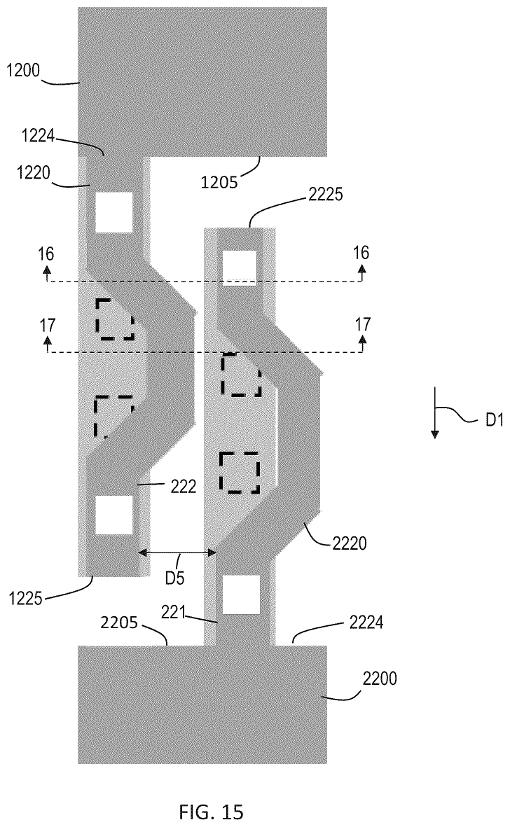

FIG. 15 illustrates a portion of the device of FIG. 14. Specifically two adjacent extended connection lines 1220 and 2220 are illustrated. As shown, each respective pair of adjacent extended connection lines 1220 and 2220 are separated, in the direction perpendicular to direction D1, by a distance D5 from sidewall 222 to sidewall 221.

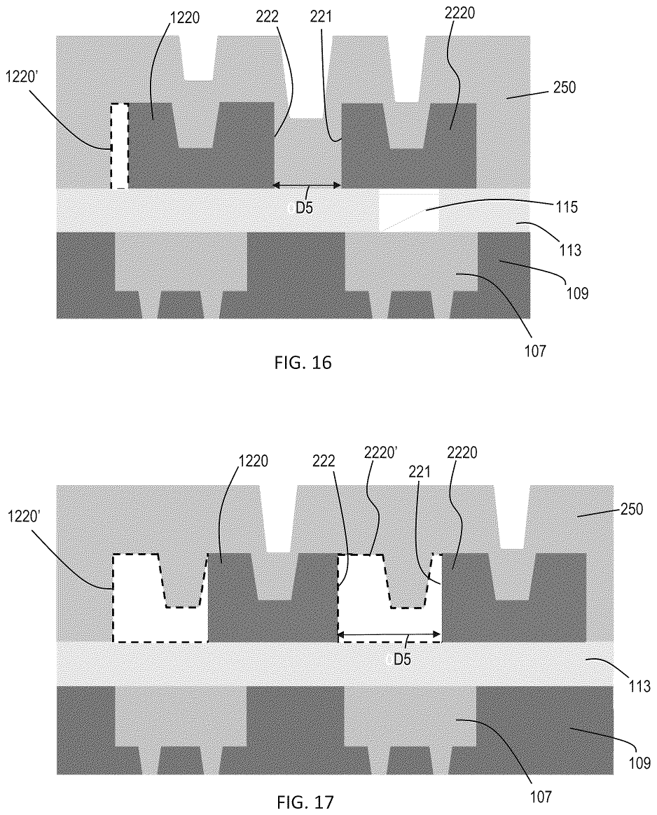

FIG. 16 is a cross-sectional view of the device of FIG. 15, taken along line 16-16 in FIG. 15 perpendicular to distance D1. As shown, the FIG. 16, the extended connection line 1220 is moved laterally, relative to the location 1220′ of the extended connection line 1220 at end wall 1224, toward extended connection line 2220. Extended connection line 2220 is not moved laterally.

FIG. 17 is a cross-sectional view of the device of FIG. 15, taken along line 17-17 in FIG. 15 perpendicular to distance D. As shown, the FIG. 17, the extended connection line 1220 is moved laterally, relative to the location 1220′ of the extended connection line 1220 at end wall 1224, toward extended connection line 2220. Further, extended connection line 2220 is moved laterally, relative to the location 2220′ of the extended connection line 2220 at end wall 2224, away from extended connection line 1220.

Cross-referencing FIGS. 15-17, the distance D5 between adjacent sidewalls 221 and 222, varies along the length of the extended connection lines 1220 and 2220 in the direction D1.

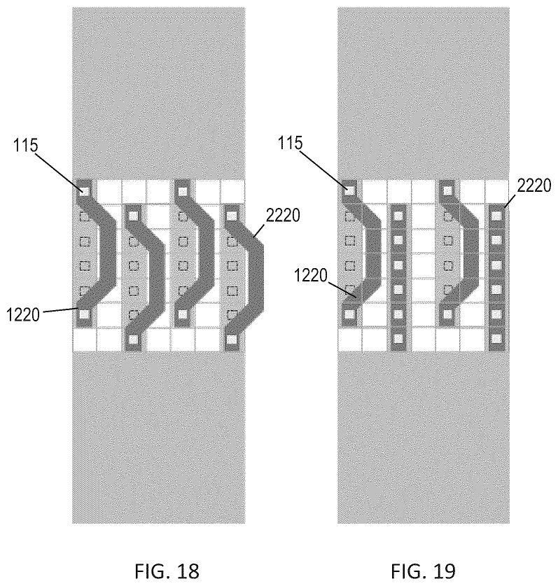

FIGS. 18-35 illustrate various designs of other embodiments in which extended connection lines 1220 and 2220 of adjacent pads 1200 and 2200 are formed with non-linear geometries.

For example, in FIG. 18, each extended connection line 1220 and 2220 is electrically connected to two respective redistribution vias 115. More particularly, each extended connection line 1220 and 2220 is electrically connected to a respective redistribution via 115 adjacent proximal end 224 and is electrically connected to a respective redistribution via 115 adjacent terminal end 225. Among the four illustrated extended connection lines 1220 and 2220, there are connections to eight redistribution vias 115.

In FIG. 19, extended connection lines 1220 have a structure similar to FIG. 18, while extended connection lines 2220 are linear. Among the four illustrated extended connection lines 1220 and 2220, there are connections to sixteen redistribution vias 115.

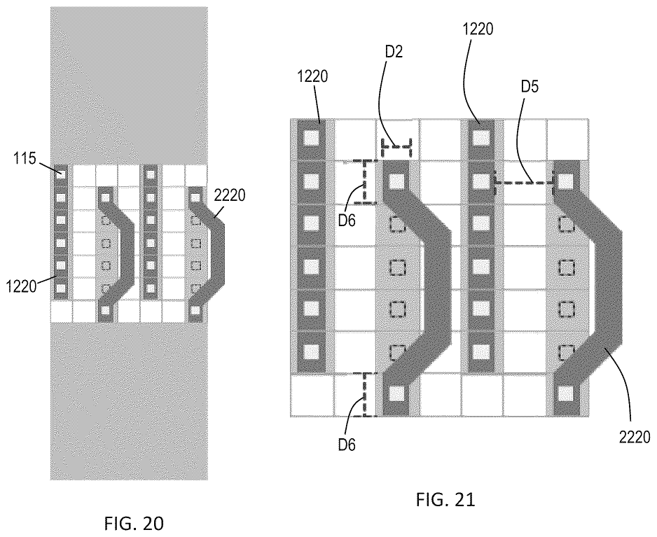

In FIG. 20, extended connection lines 2220 have a structure similar to FIG. 18, while extended connection lines 1220 are linear. Among the four illustrated extended connection lines 1220 and 2220, there are connections to sixteen redistribution vias 115.

FIG. 21 is a focused view of the extended connection lines 1220 and 2220 of the embodiment of FIG. 20. As shown, extended connection line 2220 have a parallel length equal to distance D6, a thickness equal to distance D2, and inter-line spacing equal to distance D5. As noted above, the inter-line spacing varies along the length of the extended connection line 2220.

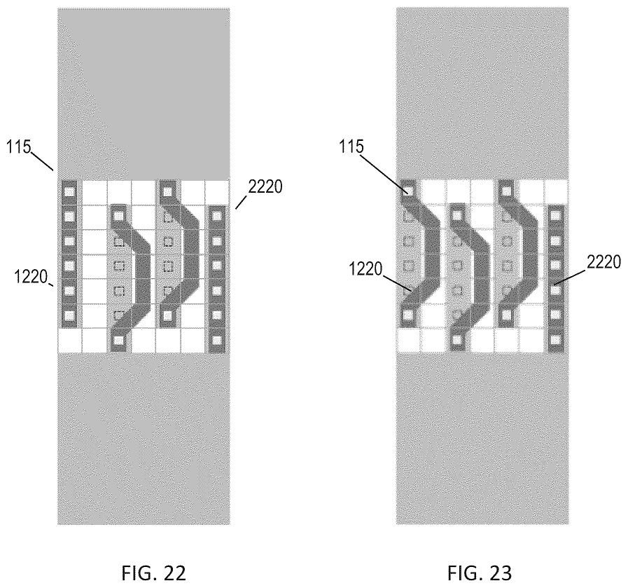

FIG. 22 illustrates an embodiment with a linear extended connection line 1220, a non-linear extended connection line 1220, a linear extended connection line 2220, and a non-linear extended connection line 2220. Among the four illustrated extended connection lines 1220 and 2220, there are connections to sixteen redistribution vias 115.

FIG. 23 illustrates an embodiment with non-linear extended connection lines 1220, a linear extended connection line 2220, and a non-linear extended connection line 2220. Among the four illustrated extended connection lines 1220 and 2220, there are connections to twelve redistribution vias 115.

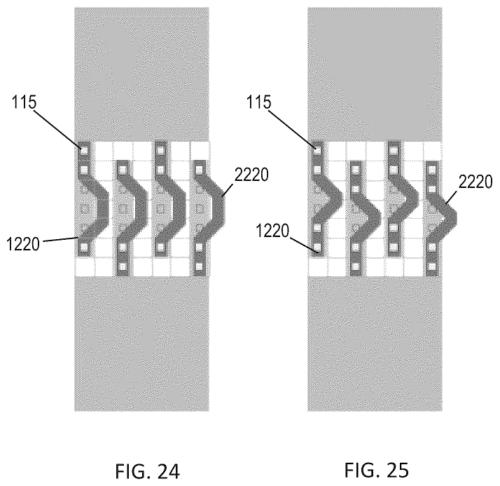

In FIG. 24, extended connection lines 1220 and 2220 all have non-linear geometries. Further, each extended connection line 1220 and 2220 includes connections to three respective redistribution vias 115. Among the four illustrated extended connection lines 1220 and 2220, there are connections to twelve redistribution vias 115.

In FIG. 25, extended connection lines 1220 and 2220 all have non-linear geometries. Further, each extended connection line 1220 and 2220 includes connections to four respective redistribution vias 115. Among the four illustrated extended connection lines 1220 and 2220, there are connections to sixteen redistribution vias 115.

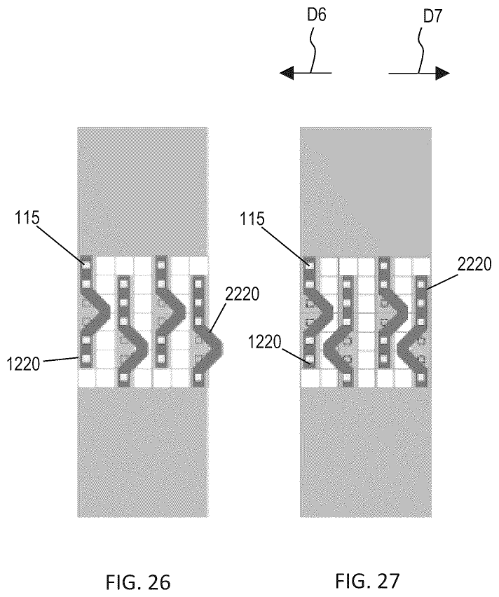

In FIG. 26, extended connection lines 1220 and 2220 all have non-linear geometries. Further, each extended connection line 1220 and 2220 includes connections to four respective redistribution vias 115. Among the four illustrated extended connection lines 1220 and 2220, there are connections to sixteen redistribution vias 115.

In FIG. 27, extended connection lines 1220 and 2220 all have non-linear geometries. Further, each extended connection line 1220 and 2220 includes connections to four respective redistribution vias 115. Among the four illustrated extended connection lines 1220 and 2220, there are connections to sixteen redistribution vias 115.

In FIG. 27, extended connection lines 1220 bend in direction D6, while extended connection lines 2220 bend in direction D7. In other words, adjacent pairs of extended connection lines 1220 and 2220 bend toward one another.

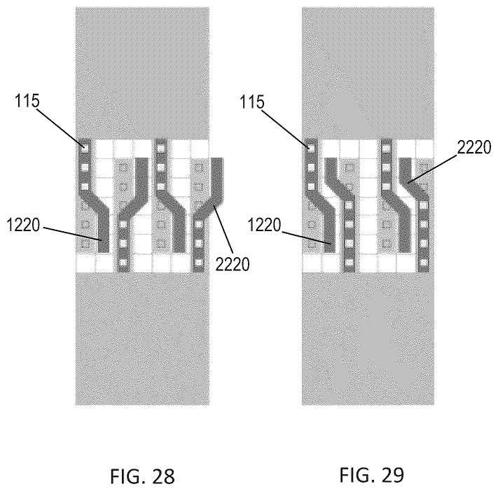

In FIG. 28, extended connection lines 1220 and 2220 all have non-linear geometries. Further, each extended connection line 1220 and 2220 includes connections to three respective redistribution vias 115. In FIG. 28, the redistribution vias 115 are connected near the proximal end 224, each terminal end remain disconnected. Among the four illustrated extended connection lines 1220 and 2220, there are connections to twelve redistribution vias 115.

FIG. 29 presents an embodiment similar to FIG. 28, but in which adjacent pairs of extended connection lines 1220 and 2220 bend toward one another (similar to FIG. 27). Further, in FIG. 29, the extended connection lines 1220 includes connections to three respective redistribution vias 115 while the extended connection lines 2220 includes connections to four respective redistribution vias 115. Among the four illustrated extended connection lines 1220 and 2220, there are connections to fourteen redistribution vias 115.

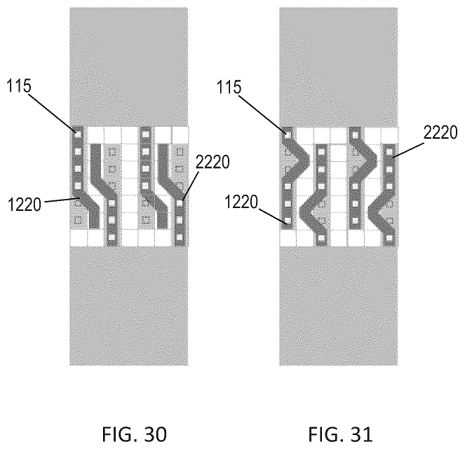

FIG. 30 illustrates an embodiment similar to FIG. 29 but in which the extended connection lines 1220 includes connections to four respective redistribution vias 115 while the extended connection lines 2220 includes connections to three respective redistribution vias 115. Among the four illustrated extended connection lines 1220 and 2220, there are connections to fourteen redistribution vias 115.

In FIG. 31, extended connection lines 1220 and 2220 all have non-linear geometries. In FIG. 31, adjacent pairs of extended connection lines 1220 and 2220 bend toward one another (similar to FIG. 27). Further, each extended connection line 1220 and 2220 includes connections to four respective redistribution vias 115. Among the four illustrated extended connection lines 1220 and 2220, there are connections to sixteen redistribution vias 115.

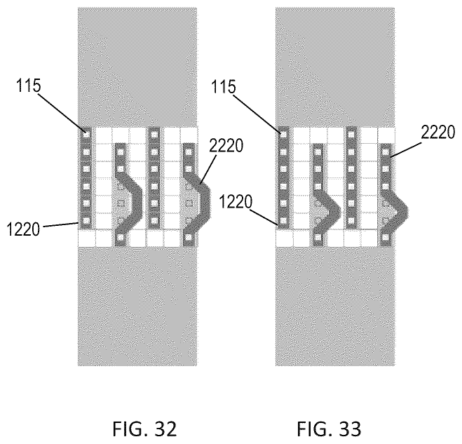

In FIG. 32, extended connection lines 1220 are linear and extended connection lines 2220 are non-linear. Each extended connection line 1220 is electrically connected to six redistribution vias 115, and each extended connection line 2220 is electrically connected to three redistribution vias 115. Among the four illustrated extended connection lines 1220 and 2220, there are connections to eighteen redistribution vias 115.

In FIG. 33, extended connection lines 1220 are linear and extended connection lines 2220 are non-linear. Each extended connection line 1220 is electrically connected to six redistribution vias 115, and each extended connection line 2220 is electrically connected to four redistribution vias 115. Among the four illustrated extended connection lines 1220 and 2220, there are connections to twenty redistribution vias 115.

Various embodiments include an extended connection line with a connection to a redistribution via 115 adjacent proximal end 224 and a connection to a redistribution via 115 adjacent distal end 225, creating a closed bend, i.e., a middle portion of the extended connection line is not-aligned with the underlying top metal feature. Other embodiments include an extended connection line with a connection to a redistribution via 115 adjacent proximal end 224 and no connection to a redistribution via 115 adjacent distal end 225, creating an open bend, i.e., the terminal portion of the extended connection line is not-aligned with the underlying top metal feature.

While certain structure designs are illustrated and described in connection with various Figures above, it is noted that any design feature from one embodiment may be used with another. For example, an extended connection line illustrated in one embodiment may be combined with an extended connection line illustrated in another embodiment.

Further, extended connection lines may be designed with any suitable geometric shape and with any suitable number of connections to redistribution vias as is desired.

Cross-referencing FIG. 12 and FIGS. 18-33, it is noted that the length of long sidewall 301 may be selected to determine the number of redistribution vias that the proximal linear section 300 may lie directly over and be electrically connected to. Likewise, in embodiments in which the terminal linear section 700 lies directly over redistribution vias, the length of long sidewall 701 may be selected to determine the number of redistribution vias that the terminal linear section 700 may lie directly over and be electrically connected to.

In certain embodiments, the parallel length D6 is 45 um and the distance D5 is 2.25 um. In certain embodiments, the parallel length D6 is 60 um and the distance D5 is 3 um. In certain embodiments, the parallel length D6 is 90 um and the distance D5 is 4.5 um. In certain embodiments, the parallel length D6 is 5000 um and the distance D5 is 250 um.

In certain embodiments, parallel length D6 may be at least 20 um, such as at least 30 um, at least 40 um, at least 45 um, at least 50 um, at least 60 um, at least 70 um, at least 80 um, at least 90 um, at least 100 um, at least 200 um, at least 500 um, at least 1000 um, at least 2000 um, at least 3000 um, at least 4000 um, or at least 5000 um. Further, parallel length D6 may be at most 20 um, such as at most 30 um, at most 40 um, at most 45 um, at most 50 um, at most 60 um, at most 70 um, at most 80 um, at most 90 um, at most 100 um, at most 200 um, at most 500 um, at most 1000 um, at most 2000 um, at most 3000 um, at most 4000 um, or at most 5000 um.

In certain embodiments, parallel length D6 may be at least 1 um, such as at least 1.5 um, at least 1.75 um, at least 2 um, at least 2.25 um, at least 2.5 um, at least 2.75 um, at least 3 um, at least 3.25 um, at least 3.5 um, at least 3.75 um, at least 4 um, at least 4.25 um, at least 4.5 um, at least 4.75 um, at least 5 um, at least 6 um, at least 7 um, at least 8 um, at least 9 um, at least 10 um, at least 25 um, at least 50 um, at least 100 um, at least 150 um, at least 200 um, at least 250 um, or at least 300 um. In certain embodiments, parallel length D6 may be at most 1 um, such as at most 1.5 um, at most 1.75 um, at most 2 um, at most 2.25 um, at most 2.5 um, at most 2.75 um, at most 3 um, at most 3.25 um, at most 3.5 um, at most 3.75 um, at most 4 um, at most 4.25 um, at most 4.5 um, at most 4.75 um, at most 5 um, at most 6 um, at most 7 um, at most 8 um, at most 9 um, at most 10 um, at most 25 um, at most 50 um, at most 100 um, at most 150 um, at most 200 um, at most 250 um, or at most 300 um.

In certain embodiments, distance D5 is at least 5% of parallel length D6, for example at least 10%, at least 15%, at least 20%, at least 25%, at least 33%, or at least 50% of parallel length D6. In certain embodiments, distance D5 is at most 5% of parallel length D6, for example at most 10%, at most 15%, at most 20%, at most 25%, at most 33%, or at most 50% of parallel length D6.

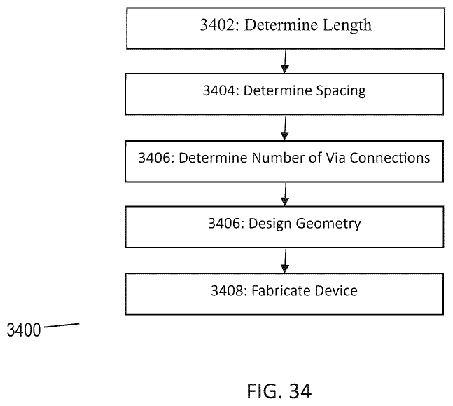

FIG. 34 is a flow chart illustrating a method 3400 for fabricating a device. At block 3402, method 3400 includes determining a length of extended conductive lines for a pad or pads.

At block 3404, method 3400 includes determining the spacing between adjacent extended conductive lines.

At block 3406, method 3400 includes determining the number of via connection between each extended conductive line and underlying top metal features through redistribution vias.

At block 3408, method 3400 includes designing a geometry of each extended conductive line, including from linear and non-linear geometries.

At block 3410, method 3400 includes fabricating a device with the extended conductive lines having the designed geometries.

In one embodiment, a semiconductor structure includes an interconnect structure lying over a semiconductor substrate and having a top metal feature; a pad lying over the interconnect structure; and an extended conductive line having a proximal end electrically connected to the pad and extending to a distal end, wherein the extended conductive line include a proximal portion extending in a first direction and a non-proximal portion extending in second direction transverse to the first direction, and wherein the extended conductive line is electrically connected to the top metal feature.

In certain embodiments of the semiconductor structure, the extended conductive line is integral with the pad.

In certain embodiments of the semiconductor structure, the extended conductive line is electrically connected to the top metal feature by a redistribution via.

In certain embodiments of the semiconductor structure, the extended conductive line is electrically connected to the top metal feature by a selected number of redistribution vias.

In certain embodiments of the semiconductor structure, the non-proximal portion is a middle portion; the extended conductive line further includes a terminal portion connected to the middle portion; and the terminal portion extends in the first direction and is aligned with the proximal portion.

In certain embodiments of the semiconductor structure, the proximal portion of the extended conductive line is electrically connected to the top metal feature by a selected number of redistribution vias.

In certain embodiments of the semiconductor structure, the terminal portion of the extended conductive line is electrically connected to the top metal feature by a selected number of redistribution vias.

In another embodiment, a semiconductor structure includes an interconnect structure lying over a semiconductor substrate and having top metal features; a first pad lying over the interconnect structure; first extended conductive lines having proximal ends electrically connected to the first pad and extending to distal ends; a second pad lying over the interconnect structure; and second extended conductive lines having proximal ends electrically connected to the second pad and extending to distal ends; wherein the first extended conductive lines and second extended conductive lines are interleaved, wherein an adjacent first extended conductive line and second extended conductive line spaced apart from one another at the proximal ends by a first distance; and wherein at least one of the adjacent first extended conductive line and second extended conductive line is non-linear such that non-proximal portions of the first extended conductive line and second extended conductive line are spaced apart by a second distance different from the first distance.

In certain embodiments of the semiconductor structure, the adjacent first extended conductive line and second extended conductive line bend toward one another.

In certain embodiments of the semiconductor structure, the adjacent first extended conductive line and second extended conductive line bend away from one another.

In certain embodiments of the semiconductor structure, the adjacent first extended conductive line has a linear proximal portion extending in a first direction and a non-proximal portion extending in second direction transverse to the first direction.

In certain embodiments of the semiconductor structure, the adjacent first extended conductive line has a linear distal portion extending in the first direction and co-linear with the proximal portion.

In certain embodiments of the semiconductor structure, the proximal portion of each extended conductive line is electrically connected to respective top metal features by a selected number of redistribution vias.

In certain embodiments of the semiconductor structure, the linear distal portion of each extended conductive line is electrically connected to respective top metal features by a selected number of redistribution vias.

In certain embodiments of the semiconductor structure, each extended conductive line is electrically connected to a respective top metal feature by at least one redistribution via.

In certain embodiments of the semiconductor structure, each extended conductive line is electrically connected to a respective top metal feature by a selected number of redistribution vias.

In another embodiment, a method for fabricating a semiconductor structure is provided and includes determining a length of extended conductive lines for interconnecting a pad to redistribution vias; determining an initial spacing between the extended conductive lines; determining a number of via connections to respective redistribution vias for each extended conductive line; designing a geometry of each extended conductive line to provided desired spacing between non-proximal portions of the extended conductive lines; and fabricating the semiconductor structure including the extended conductive lines with the designed geometry and desired spacing, wherein at least one extended conductive line has a non-linear geometry.

In certain embodiments of the method, the pad includes a first pad and a second pad; the extended conductive lines include first extended conductive lines for interconnecting the first pad to first redistribution vias and second extended conductive lines for interconnecting the second pad to second redistribution vias; and the initial spacing is between adjacent first extended conductive lines and second extended conductive lines.

In certain embodiments of the method, the first pad and the second pad are electrically connected.

In certain embodiments of the method, the desired spacing is at least 5% of the length.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure comprising:
an interconnect structure lying over a semiconductor substrate and having a top metal feature;
a pad lying over the interconnect structure; and
an extended conductive line having a proximal end electrically connected to the pad and extending to a distal end, wherein the extended conductive line include a proximal portion extending in a first direction and a non-proximal portion extending in second direction transverse to the first direction, and wherein the extended conductive line is electrically connected to the top metal feature.

2. The semiconductor structure of claim 1, wherein the extended conductive line is integral with the pad.

3. The semiconductor structure of claim 1, wherein the extended conductive line is electrically connected to the top metal feature by a redistribution via.

4. The semiconductor structure of claim 1, wherein the extended conductive line is electrically connected to the top metal feature by a selected number of redistribution vias.

5. The semiconductor structure of claim 1, wherein:
the non-proximal portion is a middle portion;
the extended conductive line further comprises a terminal portion connected to the middle portion; and
the terminal portion extends in the first direction and is aligned with the proximal portion.

6. The semiconductor structure of claim 5, wherein the proximal portion of the extended conductive line is electrically connected to the top metal feature by a selected number of redistribution vias.

7. The semiconductor structure of claim 5, wherein the terminal portion of the extended conductive line is electrically connected to the top metal feature by a selected number of redistribution vias.

8. A semiconductor structure comprising:
an interconnect structure lying over a semiconductor substrate and having top metal features;
a first pad lying over the interconnect structure;
first extended conductive lines having proximal ends electrically connected to the first pad and extending to distal ends;
a second pad lying over the interconnect structure;
second extended conductive lines having proximal ends electrically connected to the second pad and extending to distal ends;
wherein the first extended conductive lines and second extended conductive lines are interleaved, wherein an adjacent first extended conductive line and second extended conductive line spaced apart from one another at the proximal ends by a first distance; and
wherein at least one of the adjacent first extended conductive line and second extended conductive line is non-linear such that non-proximal portions of the first extended conductive line and second extended conductive line are spaced apart by a second distance different from the first distance.

9. The semiconductor structure of claim 8, wherein the adjacent first extended conductive line and second extended conductive line bend toward one another.

10. The semiconductor structure of claim 8, wherein the adjacent first extended conductive line and second extended conductive line bend away from one another.

11. The semiconductor structure of claim 8, wherein the adjacent first extended conductive line has a linear proximal portion extending in a first direction and a non-proximal portion extending in second direction transverse to the first direction.

12. The semiconductor structure of claim 11, wherein the adjacent first extended conductive line has a linear distal portion extending in the first direction and co-linear with the proximal portion.

13. The semiconductor structure of claim 12, wherein the proximal portion of each extended conductive line is electrically connected to respective top metal features by a selected number of redistribution vias.

14. The semiconductor structure of claim 13, wherein the linear distal portion of each extended conductive line is electrically connected to respective top metal features by a selected number of redistribution vias.

15. The semiconductor structure of claim 11, wherein each extended conductive line is electrically connected to a respective top metal feature by at least one redistribution via.

16. The semiconductor structure of claim 11, wherein each extended conductive line is electrically connected to a respective top metal feature by a selected number of redistribution vias.

17. A method for fabricating a semiconductor structure comprising:
determining a length of extended conductive lines for interconnecting a pad to redistribution vias;
determining an initial spacing between the extended conductive lines;
determining a number of via connections to respective redistribution vias for each extended conductive line;
designing a geometry of each extended conductive line to provided desired spacing between non-proximal portions of the extended conductive lines; and
fabricating the semiconductor structure including the extended conductive lines with the designed geometry and desired spacing, wherein at least one extended conductive line has a non-linear geometry.

18. The method of claim 17, wherein:
the pad includes a first pad and a second pad;
the extended conductive lines include first extended conductive lines for interconnecting the first pad to first redistribution vias and second extended conductive lines for interconnecting the second pad to second redistribution vias; and
the initial spacing is between adjacent first extended conductive lines and second extended conductive lines.

19. The method of claim 18, wherein the first pad and the second pad are electrically connected.

20. The method of claim 18, wherein the desired spacing is at least 5% of the length.
